(19) United States
(12) Patent Application Publication
(10) Pub. No.: US 2014/0204513 A1
(43) Pub. Date: Jul. 24, 2014

(54) CASING ATTACHMENT FOR A MOBILE ELECTRONIC DEVICE WITH LIQUID CONTAINER AND ATOMIZING MEANS

(71) Applicants: Maria Maddalena Del Padre, Cassino (IT); Sergio Mattia, Piedimonte San Germano (IT); Yulia Kapranova, Starnberg (DE)

(72) Inventors: Maria Maddalena Del Padre, Cassino (IT); Sergio Mattia, Piedimonte San Germano (IT); Yulia Kapranova, Starnberg (DE)

(73) Assignee: INNOVANTIX GMBH, Muenchen (DE)

(21) Appl. No.: 14/238,030

(22) PCT Filed: Aug. 10, 2011
(86) PCT No.: PCT/EP2011/063741

§ 371 Date: Mar. 21, 2014

(51) Int. Cl. B05B 15/06; H05K 5/00

(52) U.S. Cl. CPC B05B 15/06; H05K 5/0086
USPC 361/679.01; 239/289

(57) ABSTRACT

A casing attachment for a mobile electronic device is configured for mounting the attachment on the casing of the mobile electronic device and includes an atomizing unit having an atomizer and a liquid container for atomizing liquids.

### BACKGROUND OF THE INVENTION

The present invention relates to extending the capabilities of mobile electronic devices to store and carry liquids in protective casings for use in various fields of application, It relates to mobile electronic devices like mobile phones, mobile music and video players and the like.

Relatively often people get into situations when they are missing little volumes of several liquids/fragrances which could significantly help them to feel more comfortable in different moments of their lifes. This relates to liquid substances in several forms, such as perfumes, deodorants, disinfectants (i.e. hand sanitizers), insect repellents, aftershaves, bad breath or dry mouth remedies, visage refreshment water, OC spray (also known as pepper spray, used for self-defense) etc.

In many cases people do not want to carry bags or clutches when being in clubs or dancing venues or having dates or outdoor activities. The only things they usually keep in their pockets are keys, a wallet and a mobile phone or any other mobile device. So people have to compromise between “agility” and habitual things that create a feeling of comfort.

Thus, an object underlying the invention is to create an arrangement enabling a person to carry along different items allowing an increase in the functionality and a simplification of the use of the items to be carried along in a manner which is as simple as possible and with the least possible material requirements.

### SUMMARY OF THE INVENTION

According to the invention this object is achieved by a casing attachment for a mobile electronic device comprising mounting structure (device) for its mounting onto the casing of a mobile electronic device as well as an atomizing unit having an atomizer and a liquid container for atomizing liquid. This allows having the most required liquids at hand every time and everywhere in the same way as the permanent companions of daily life such as mobile phones or other electronic devices. These devices exist in various shapes and for different purposes, for example MP3 players, mobile phones, smartphones, netbooks, tablet computers, and are nowadays available for people of all ages and gender practically anytime, anywhere.

The omnipresence of the modern mobile electronic devices makes them also a viable and always available means for carrying along substances needed for daily care, such that a person taking along the mobile electronic device has to carry a minimum of items, since the above-described comfort or health critical liquids are embedded in the mobile device, such as for example mobile phones, smartphones, netbooks, MP3 players and others.

The liquid containers according to the invention can be used in the form of units for one use or as rechargeable reloading units containing the liquid.

The term “liquids” generally means liquids with any variety of density. In the case of a mobile phone the reloading units could be provided in the form of cartridges held on the back of the device above the battery, i.e. on the side facing away from the display, and the content of which is sprayed with an integrated atomizer. Chargers for the reloading units can be provided in the form of “docking” bottles or containers into which the liquid containers can be inserted for reloading by sliding or pushing them into a slot and reloading them by manual intervention. Shopping centers might offer the use of automatic docking stations where the liquid containers can be recharged with different varieties of liquids.

A preferred embodiment of the invention provides that the casing attachment is equipped with a receiver for receiving and releasably accommodating the atomizing unit. This allows replacing the liquid container together with the atomizer by a new liquid container and atomizer after the liquid in the liquid container has been consumed.

A further preferred embodiment of the present invention provides that the mounting device for attachment of the casing is a snapping slip-on fastener having elastic gripping elements which conform in form with at least a part of the casing of the mobile electronic device, which allows a releasable fixing of the casing attachment on the casing of the mobile electronic device.

It is particularly advantageous if the number and the arrangement of the elastic gripping elements correspond to the number and arrangement of the casing corners of the mobile electronic device, wherein the casing corners can be at least partially encompassed by the elastic gripping elements. This allows a particularly simple and compact construction of the casing attachment with a reliable mounting by the abovementioned snapping slip-on fastener. A further advantage of this embodiment consists in the fact that the casing attachment can be used for each already existing casing without the necessity of further measures to be taken with regard to the casing of the mobile electronic device.

The present invention is particularly advantageous if the casing attachment is used for a mobile phone, because this is an item which is most frequently carried along.

It is convenient that the casing attachment according to the invention comprises at least one constructional element allowing the actuation of the mobile electronic device when the casing attachment is mounted on the mobile electronic device. In the case of a mobile phone, a preferred constructional element forms an opening, the position of which, in its condition mounted on the mobile phone, corresponds to the position of a lens integrated into the mobile phone. Further openings or cutouts on the casing attachment can allow free access to further control elements of the mobile phone.

Preferably, the atomizer and the liquid container are separate parts which are detachably connected to each other.

A further object of the invention is a mobile electronic device comprising a casing attachment, embodiments of which are described herein.

### BRIEF DESCRIPTION OF THE DRAWINGS

Embodiments of the invention are explained in detail by means of the attached drawings, in which

FIG. 1 shows an exploded perspective view of a casing attachment according to the invention comprising an atomizer and a liquid container,

FIG. 2 shows an exploded perspective view of a mobile phone and the casing attachment,

FIG. 3 shows a perspective rear view of the mobile phone of FIG. 2 with mounted casing attachment,

FIG. 4 shows a perspective front view of the mobile phone of FIG. 2 with mounted casing attachment.

### DETAILED DESCRIPTION OF THE INVENTION

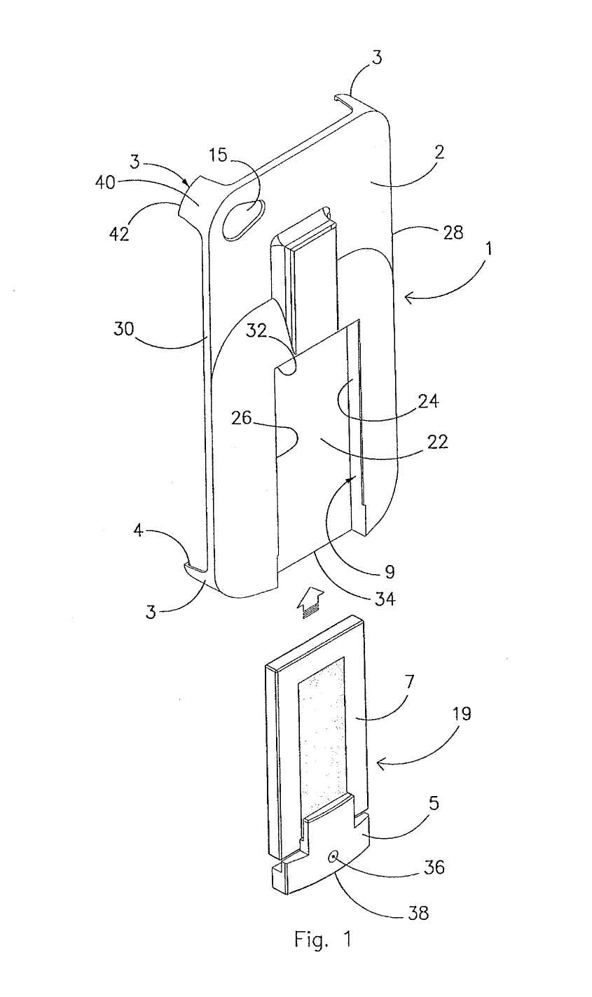

FIG. 1 shows in its upper part a planar rectangular casing attachment 1 with a base plate 2 having a generally rectangular form with rounded corners, wherein at the back side of the base plate 2 facing a mobile phone a gripping element 3 extending generally perpendicular to the base plate 2 is provided at each of the four rounded corners. Each gripping element 3 comprises a web portion 40 extending generally perpendicular to the base plate 2, the cross-section form of the web portion 40 parallel to the base plate 2 generally corresponding to the form of the rounding of the corner of the base plate 2, and a free edge 42 running parallel to the base plate 2, from which a gripping protrusion 4 of small height extends inwardly parallel to the base plate 2.

Receiving structure (receiver) 9 is positioned on the front side of the base plate 2, which receiver 9 comprises a rectangular receiving groove 22, the two longitudinal side walls 22, 26 of which run parallel to the side edges 28, 30 of the base plate 2 and extend perpendicularly to the base plate 2. The receiving groove 22 is open at the lower edge 34 of the base plate 2 and is limited at the top by an end wall 32 running perpendicularly to the side edges 28, 30 of the base plate 2. The bottom of the receiving groove 22 is formed by the base plate 2.

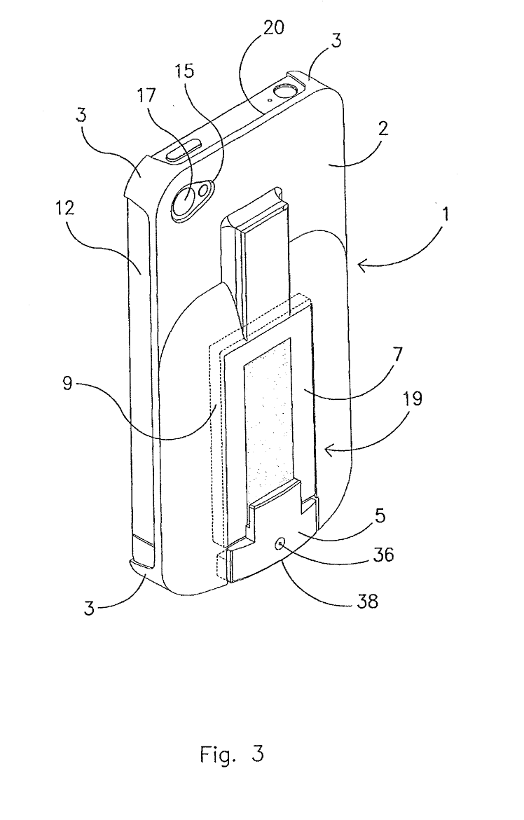

In the upper, in FIG. 1 left, corner of the base plate 2 a drop-shaped opening 15 is located, the position of which corresponds to the position of a lens 17 of the mobile phone 10 as shown in FIG. 3.

In the lower part of FIG. 1 a liquid container 7 with atomizer 5 mounted thereon is shown, wherein the liquid container 7 and the atomizer 5 form a substantially cuboid atomizing unit 19 with small height, which can be releasably inserted from below into the receiving groove 22 of the receiving unit 9. The parallel side edges of the rectangular unit 19 are formed form-fittingly with the side walls 24, 26 of the receiver 9, such that the unit 19 is held in the receiver 9 by tight fit as shown in FIG. 3. The atomizer 5, which is provided with an atomizing device in the form of an atomizing nozzle 36, is arranged such that its lower edge 38 is flush with the lower edge 34 of the base plate 2.

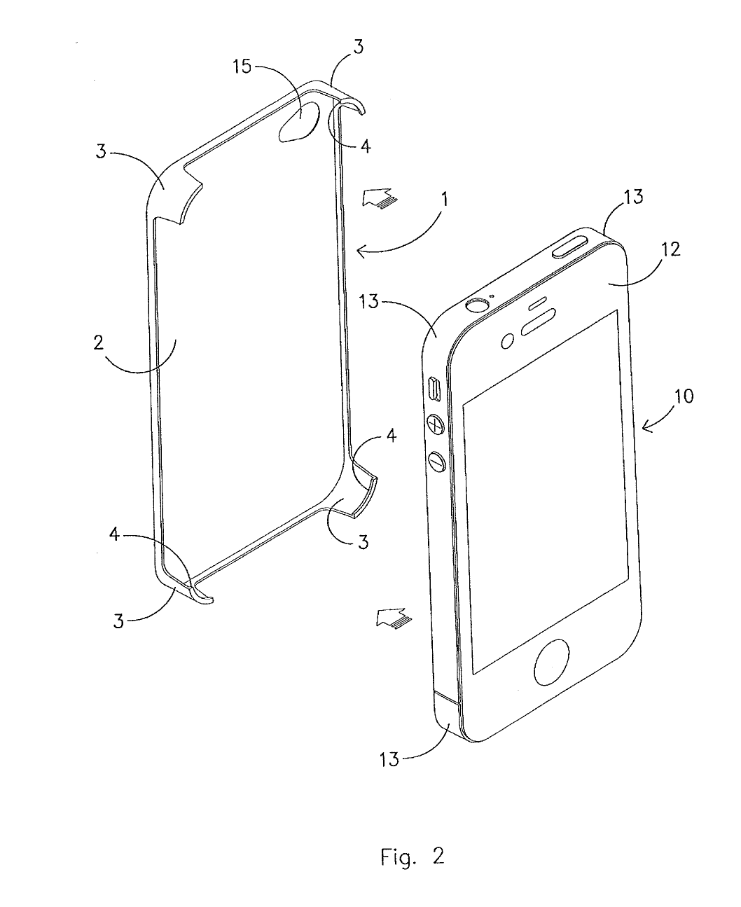

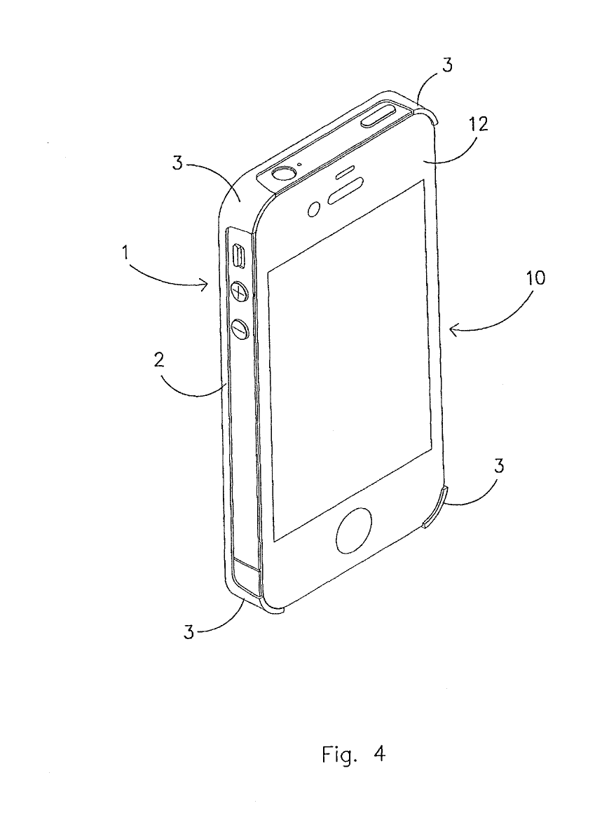

The left part of FIG. 2 shows a perspective view of the back side of the casing attachment 1 facing the mobile phone 10. The gripping elements 3 are elastically formed such that they are externally bent around the corners 13 of the mobile phone 10, when the casing attachment 1 is slipped onto the mobile phone 10, which results in a snapping slip-on fastening between the two parts when the device-facing surface of the base plate 2 contacts the attachment-facing surface of the mobile phone 10, whereby a reliable hold of the casing attachment 1 on the mobile phone 10 is assured by the gripping protrusions 4 abutting at the side which is facing away from the casing attachment, as shown in FIG. 4. The elastic gripping elements 3 have the same rounded form as the rounded edges 13 of the mobile phone 10, which increases the stiffness of the gripping elements 3 and results in a compact form of the casing attachment with the mobile phone 10 in the mounted condition.

FIG. 3 shows the front side of the casing attachment 1 in the condition in which it is mounted on the electronic device 10 and in which the unit 19 comprising the liquid container 7 and the atomizer 5 is inserted in the receiving groove 22. The base plate 2 comprises in its upper area an opening 15 corresponding to a lens 17 of the mobile electronic device 10. Further constructional elements of the casing attachment 1 allowing access to the control elements of a mobile electronic device 10 are possible. As an example FIG. 3 shows a recess 20 at the upper edge of the casing attachment 1 allowing access to a button and a connection on the upper side of the mobile electronic device 10. Alternatively, constructional elements in the form of openings and recesses can be at least partially filled with an elastic material, such as for example rubber, such that the functionality of the control elements, like buttons, is not impaired.

FIG. 4 shows the casing attachment 1 mounted on the mobile electronic device 10 from the side of the mobile electronic device 10. By the compact construction and the snapping fit-on fastening of the casing attachment 1, all control elements of the mobile electronic device 10 remain accessible.

The device according to the invention works as follows. In an assembled state as shown in FIG. 3 the atomizer 5 at the unit 19 can be pushed by means of the finger pressure of a user effecting the atomization of the liquid contained in the liquid container 7 by the atomizer 5, as soon as the liquid exits the nozzle 36. If the liquid supply in the liquid container 7 is consumed after repeated actuation of the atomizer 5, the unit 19 can be removed from the receiver 9 by shifting it towards the bottom and can be replaced by a new unit 19 (not shown) or can be again inserted after refilling the liquid container 7 of the unit 19 which has just been removed.

1. A casing attachment for a mobile electronic device having a casing, the casing attachment comprising
mounting structure for mounting the casing attachment onto the easing of the mobile electronic device.
an atomizing unit having a liquid container and an atomizer for atomizing a liquid contained in the container, and
a receiver receiving and releasably accommodating the atomizing unit.

2. (canceled)

3. The casing attachment according to claim 1, wherein the mounting structure comprises a snapping slip-on fastener having elastic gripping elements which conform in form with at least a part of the casing of the mobile electronic device.

4. The casing attachment according to claim 3, wherein the elastic gripping elements correspond in number and arrangement to corners of the casing of the mobile electronic device, wherein the casing corners are configured to he at least partially encompassed by the elastic gripping elements.

5. The casing attachment according to claim 1, wherein the mobile electronic device is a mobile phone.

6. The casing attachment according to 1, further comprising at least one constructional element allowing actuation of the mobile electronic device when the casing attachment is mounted on the mobile electronic device.

7. The casing attachment according to claim 6, wherein the constructional element is an opening at a position which, when the casing attachment is mounted onto the casing of the mobile phone, corresponds to position of a lens of the mobile phone.

8. The casing attachment according to claim 1, wherein the at atomizer and the liquid container are separate parts which are detachably connected to each other.

9. A mobile electronic device in combination with a casing attachment according to claim 1.
